(19) United States
(12) Patent Application Publication
(10) Pub. No.: US 2013/0341747 A1
(43) Pub. Date: Dec. 26, 2013

(54) CHIP PACKAGE AND METHOD FOR FORMING THE SAME

(71) Applicant: XINTEC INC., Jhongli City (TW)

(72) Inventors: Po-Shen LIN, New Taipei City (TW); Tsang-Yu LIU, Zhubei City (TW); Yen-Shih HO, Kaohsiung City (TW); Chih-Wei HO, Zhongli City (TW); Shih-Chin CHEN, Zhubei City (TW)

(21) Appl. No.: 13/921,999

(22) Filed: Jun. 19, 2013

Related U.S. Application Data
(60) Provisional application No. 61/662,188, filed on Jun. 20, 2012.

(51) Int. Cl. H01L 31/0232; H01L 31/02

(52) U.S. Cl. CPC H01L 31/0232; H01L 31/02
USPC 257/432; 438/64; 438/65

(57) ABSTRACT

An embodiment of the invention provides a chip package which includes: a chip including: a semiconductor substrate having a first surface; a device region formed in the semiconductor substrate; and a plurality of micro-lenses on the first surface and the device region; a cover substrate disposed on the chip, wherein the cover substrate is a transparent substrate; a spacer layer disposed between the chip and the cover substrate, wherein the spacer layer, the chip, and the cover substrate collectively surround a cavity in the device region; and at least one main lens on the cover substrate and in the cavity, wherein a width of the main lens is greater than that of each of the micro-lenses.

### CROSS REFERENCE TO RELATED APPLICATIONS

This application claims the benefit of U.S. Provisional Application No. 61/662,188, filed on Jun. 20, 2012, the entirety of which is incorporated by reference herein.

### BACKGROUND OF THE INVENTION

1. Field of the Invention

The invention relates to a chip package and method for forming the same, and in particular relates to a chip package formed by using a wafer-level packaging process.

2. Description of the Related Art

The chip package packaging process is one important step when forming electronic products. A chip package not only protects the chips from environmental contaminants, but also provides electrical connections between electronic elements in the chip and electronic elements outside of the chip.

Chip package technologies which can reduce the sizes of the chip packages, can fabricate the chip packages in mass production, can ensure the quality of the chip packages, and can reduce the time and cost of fabrication, have become important issues.

### BRIEF SUMMARY OF THE INVENTION

An embodiment of the invention provides a chip package, including: a chip, including: a semiconductor substrate having a first surface and a second surface; a device region formed in the semiconductor substrate; a dielectric layer disposed on the first surface; and a conducting pad structure disposed in the dielectric layer and electrically connected to the device region; a cover substrate disposed on the chip; and a spacer layer disposed between the chip and the cover substrate, wherein a cavity is created and surrounded by the spacer layer, the chip and the cover substrate on the device region, and wherein the spacer layer directly contacts the chip, and no adhesive glue is disposed between the chip and the spacer layer.

An embodiment of the invention provides a method for forming a chip package, including: providing a wafer, including: a semiconductor substrate having a first surface and a second surface; a plurality of device regions formed in the semiconductor substrate; a dielectric layer disposed on the first surface; and a plurality of conducting pad structures disposed in the dielectric layer, and each of the conducting pad structures is electrically connected to one of the device regions; providing a cover substrate; forming a spacer layer on the wafer or the cover substrate; mounting the cover substrate onto the wafer such that the spacer layer is located between the wafer and the cover substrate, wherein a plurality of cavities is created and surrounded by the spacer layer, the wafer and the cover substrate, and each of the cavities is located over one of the device regions, and wherein the spacer layer directly contacts the wafer, and there is no adhesive glue disposed between the wafer and the spacer layer; and performing a dicing process along a plurality of predetermined scribe lines of the wafer for forming a plurality of separated chip packages.

An embodiment of the invention provides a chip package, including: a chip, including: a semiconductor substrate having a first surface; a device region formed in the semiconductor substrate; and a plurality of micro-lenses disposed on the first surface and on the device region; a cover substrate disposed on the chip, wherein the cover substrate is a transparent substrate; a spacer layer disposed between the chip and the cover substrate, wherein a cavity is created and surrounded by the spacer layer, the chip and the cover substrate on the device region; and at least one main lens disposed on the cover substrate and in the cavity, wherein a width of the main lens is greater than a width of each of the micro-lenses.

An embodiment of the invention provides a method for forming a semiconductor structure, including: providing a wafer, including: a semiconductor substrate having a first surface; a plurality of device regions formed in the semiconductor substrate; and a plurality of micro-lenses disposed on the first surface and on the device regions; providing a cover substrate; forming a plurality of main lenses on the cover substrate, wherein a width of each of the main lenses is greater than a width of each of the micro-lenses; forming a spacer layer on the wafer or the cover substrate; and mounting the cover substrate onto the wafer such that the spacer layer is located between the wafer and the cover substrate, wherein a plurality of cavities are created and surrounded by the spacer layer, the wafer and the cover substrate, and each of the cavities is located over one of the device regions, and each of the cavities accommodates at least one of the main lenses corresponding to at least two of the micro-lenses.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1F show cross-sectional views of the formation of a chip package according to an embodiment of the present invention;

FIGS. 2A and 2B respectively show top views of the chip packages according to embodiments of the present invention;

FIGS. 3A-3F show cross-sectional views of the formation of a chip package according to an embodiment of the present invention;

FIGS. 4A-4D respectively show cross-sectional views of chip packages according to embodiments of present invention;

FIGS. 5A-5B show cross-sectional views of the formation of a chip package according to an embodiment of the present invention;

FIGS. 6A-6G show cross-sectional views of the formation of a chip package according to an embodiment of the present invention;

FIG. 7 shows a cross-sectional view of a chip package according to another embodiment of the present invention;

FIG. 8 shows a cross-sectional view of a portion of the formation of a chip package according to an embodiment of the present invention;

FIG. 9 shows a cross-sectional view of a portion of the formation of a chip package according to an embodiment of the present invention; and

FIGS. 10A-10D show cross-sectional views of the formation of a chip package according to an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposed between the first and second layers.

A chip package according to an embodiment of the present invention may be used to package a variety of chips. For example, the chip package of the embodiments of the invention may be applied to active or passive elements, or electronic components with digital or analog circuits (digital or analog circuits), such as optoelectronic devices, micro electro mechanical systems (MEMS), micro fluidic systems, and physical sensors for detecting the physical quantity variation of heat, light, or pressure. Particularly, a wafer scale package (wafer scale package; WSP) process may be applied to package semiconductor chips such as image sensor devices, light-emitting diodes (light-emitting diodes; LEDs), solar cells (solar cells), RF circuits (RF circuits), accelerators (accelerators), gyroscopes (gyroscopes), micro actuators (micro actuator), surface acoustic wave devices (surface acoustic wave devices), pressure sensors (pressure sensors), ink printer heads (ink printer heads), or power MOSFET modules (power MOSFET modules).

The wafer scale package process mentioned above mainly means that after the package process is accomplished during the wafer stage, the wafer with chips is cut to independent packages. However, in a specific embodiment, separated chips may be redistributed overlying a supporting wafer and then be packaged, which may also be referred to as a wafer scale package process. In addition, the above mentioned wafer scale package process may also be adapted to form chip packages of multi-layer integrated circuit devices (multi-layer integrated circuit devices) by stacking (stack) a plurality of wafers having integrated circuits. In one embodiment, the diced package is a chip scale package (CSP). The size of the chip scale package (CSP) may be only slightly larger than the size of the packaged chip. For example, the size of the chip package is not larger than 120% of the size of the packaged chip.

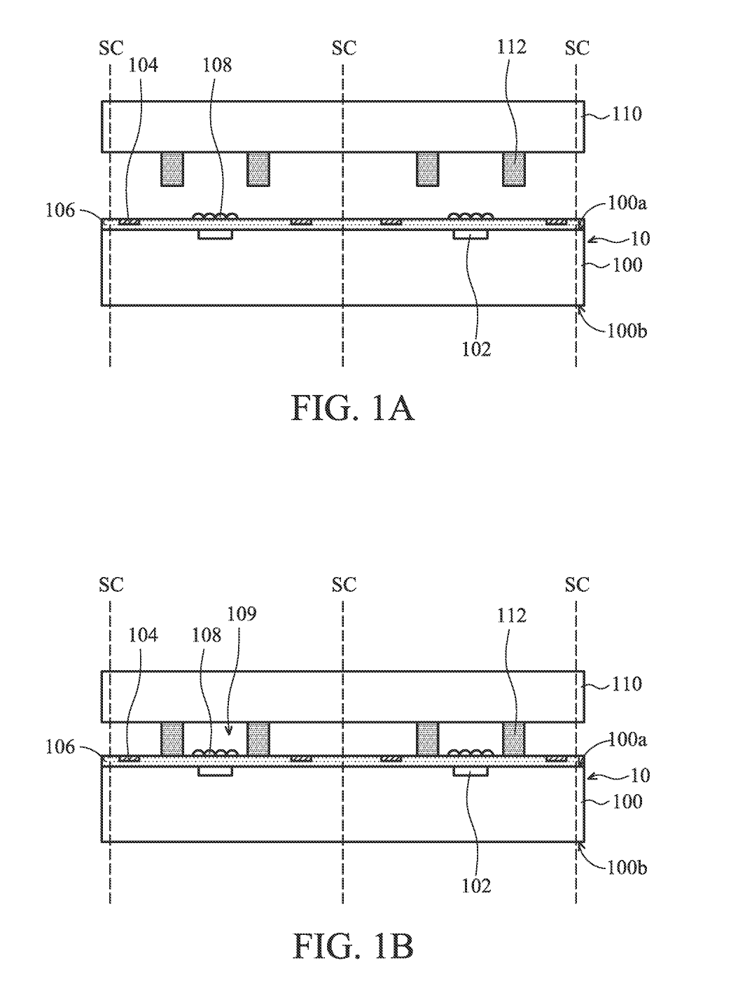

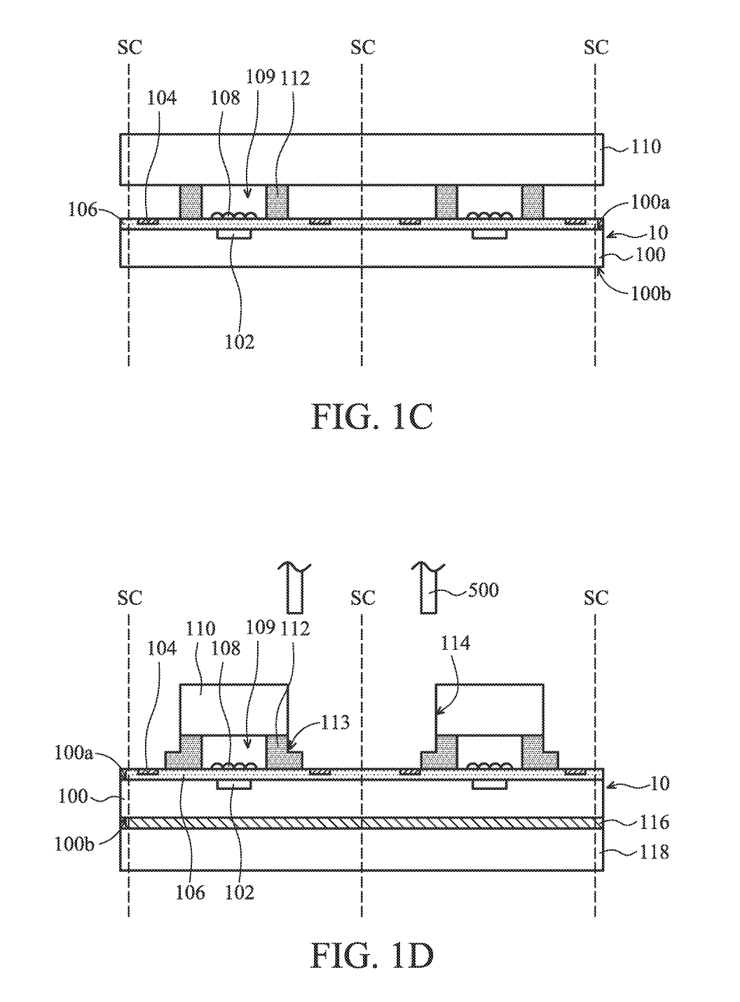

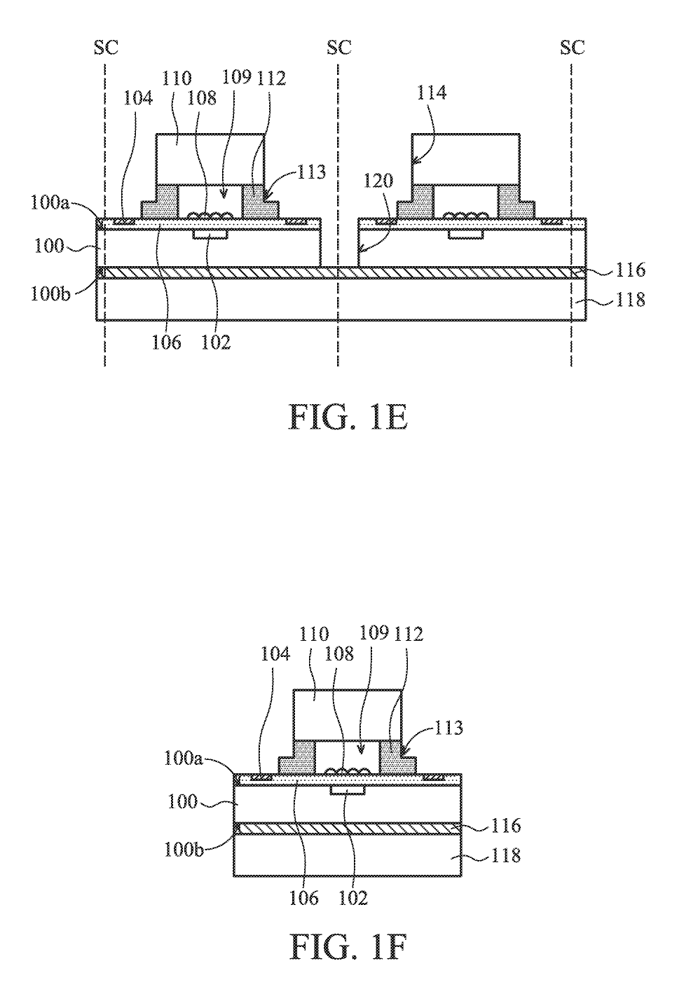

FIGS. 1A-1F show cross-sectional views of the formation of a chip package according to an embodiment of the present invention. As shown in FIG. 1A, a wafer 10 is provided. The wafer 10 may be a semiconductor wafer, such as a silicon wafer. The wafer 10 may comprise a semiconductor substrate 100 having a first surface 100a and a second surface 100b. The wafer 10 may have a plurality of predetermined scribe lines SC. The wafer 10 may also have a plurality of device regions formed in the semiconductor substrate 100. There are various devices, such as an optoelectronic device, formed in the device regions 102. The optoelectronic device may, for example, be an image sensor device or an illuminating device.

The wafer 10 may further comprise a dielectric layer 106 disposed on the surface 100a of the semiconductor substrate 100 and a plurality of conducting pad structures 104 disposed in the dielectric layer 106. Each of the conducting pad structures 104 electrically connects to one of the device regions 102. In an embodiment, an optical element 108 may be optionally formed in the device regions 102. The optical element 108 may comprise a lens/or a color filter layer.

Then, a cover substrate 110 is provided. The cover substrate 110 may have a size and profile similar to the size and profile of the wafer 10. The cover substrate 110 may be a transparent substrate, such as a glass substrate. In an embodiment, the cover substrate 110 may be an IR glass substrate.

Then, a spacer layer 112 may be formed on the wafer 10 or the cover substrate 110. In the embodiment shown in FIG. 1, the spacer layer 112 is formed on the cover substrate 110. The material of the spacer layer 112 may comprise (but is not limited to) an epoxy resin, a silicon gel polymer, or a combination thereof. In an embodiment, the spacer layer 112 may be adhesive itself and can directly bond onto the cover substrate 110 or the wafer 10. In addition, the spacer layer 112 may be cured using a curing process, such as a heating process and/or an illuminating process. In an embodiment, the spacer layer 112 comprises a photoresist material and is able to be patterned by exposure and development processes.

For example, in an embodiment, a spacer material layer (not shown) may be formed on the cover substrate 110 using a spray coating process or a spin coating process. Then, exposure and development processes may be performed to the spacer material layer for patterning the spacer material layer as the spacer layer 112 shown in FIG. 1A. In another embodiment, the steps of forming the spacer layer 112 may comprise performing multiple deposition, exposure, and development processes, for forming a stack of a plurality of patterned material layers. In this case, the spacer layer 112 may comprise a stack of a plurality of patterned material layers. These material layers may comprise the same material and have interfaces therebetween. In an embodiment, the interfaces may be detected by optical measurement or observed by electronic microscopy. In another embodiment, the materials of the material layers are not completely the same.

Then, as shown in FIG. 1B, the cover substrate 110 is mounted on the wafer 10 such that the spacer layer is located between the wafer 10 and the cover substrate 110. In an embodiment, the spacer layer 112 may be bonded to the wafer 10 since the spacer layer 112 is adhesive. Then, the spacer layer 112 may be optionally cured. Cavities 109 may be created and surrounded by the surrounding of the spacer layer 112, and the wafer 10 and the cover substrate 110. Each of the cavities 109 may be located over one of the device regions 102. The optical element 108 may be located in the cavities 109. The spacer layer 112 may directly contact the wafer 10, and no adhesive glue is disposed between the spacer layer 112 and the wafer 10. In an embodiment, the wafer 10 may comprise an optical layer (not shown, such as a color filter layer) on the semiconductor substrate 100 or a flat layer (not shown) on the semiconductor substrate 100. In this case, the spacer layer 112 may directly contact the semiconductor substrate 100, the dielectric layer 106, the optical layer on the semiconductor substrate 100, or the flat layer on the semiconductor substrate 100. Since there is no adhesive glue disposed at the two ends of the spacer layer 112, displacement between the semiconductor substrate 100 and the cover substrate 110 may be prevented. In addition, the optical element 108 on the device region 102 may be also prevented from being contaminated by the adhesive glue.

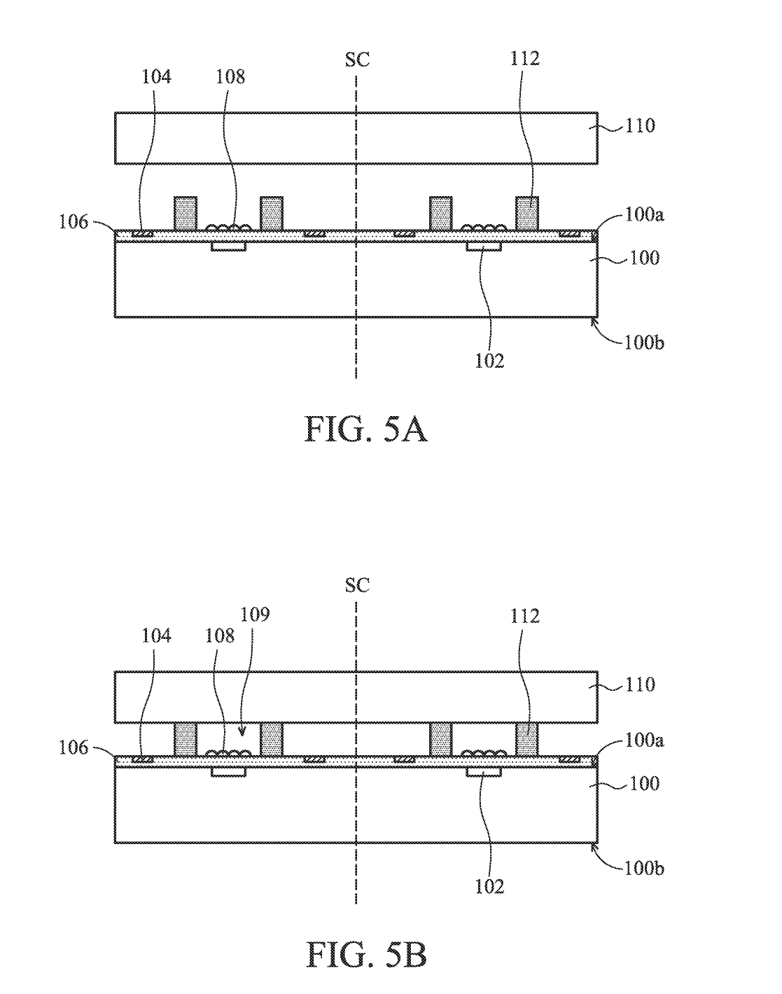

The embodiments of the present invention are not limited to this. In another embodiment, as shown in FIGS. 5A-5B, the spacer layer 112 is formed on the wafer 10 first. Then, the cover substrate 110 may be bonded onto the spacer layer 112.

As shown in FIG. 1B, in an embodiment, the projection of the spacer layer 112 on the surface 100a is located between the projection of the conducting pad structures 104 on the surface 100a and the projection of the device regions 102 on the surface 100a. In an embodiment, the projection of the spacer layer 112 on the surface 100a does not overlap the projection of the conducting pad structures 104 on the surface 100a. That is, the spacer layer 112 is not right above the conducting pad structures 104.

As shown in FIG. 1C, the wafer 10 may then be thinned, optionally. For example, a thinning process may be performed to the surface 100b of the semiconductor substrate 100 by using the cover substrate 110 as a support for thinning the semiconductor substrate 100 to a suitable thickness. The suitable thinning process may be a mechanical polishing process, an etching process, a chemical mechanical polishing process, or a combination thereof.

As shown in FIG. 1D, in an embodiment, the wafer 10 may optionally be disposed on the support substrate 118. For example, the wafer 10 may be bonded to the support substrate 118 by an adhesion layer 116. The support substrate 118 may be a semiconductor substrate, a ceramic substrate, a polymer substrate, or a combination thereof. In an embodiment, the support substrate 118 may be a glass substrate. The glass substrate (e.g., having a thickness of 100 μm) does not only function as a support, but can also prevent the formation of a parasitic capacitor between itself and the wafer and can limit RF noise.

Then, a dicing process may be performed along a plurality of scribe lines SC of the wafer 10 for forming a plurality of separated chip packages. The dicing process may be single cutting or segmented cutting processes. As shown in FIG. 1D, a dicing process may be performed first to remove a portion of the cover substrate 110 and expose the wafer 10. In an embodiment, the first dicing process further removes a portion of the spacer layer 112 and forms at least one recess 113 in the spacer layer 112. In an embodiment, a sidewall of the spacer layer 112 (such as a sidewall of the recess 113) may be substantially coplanar with a sidewall of the cover substrate 110. In addition, the first dicing process may comprise using a scribing knife to remove a first portion and a second portion of the cover substrate 110 at different times such that a portion of the cover substrate 110 between the first and second portions of the cover substrate 110 can be separated naturally. For example, a portion of the cover substrate 110 at a left side of the scribe line SC and a portion of the cover substrate 110 at a right side of the scribe line SC are diced at different times such that the middle portion of the cover substrate 110 can be separated naturally. After the first dicing process, an opening 114 exposing the wafer 10 may be formed in the cover substrate 110. However, it should be noted that the embodiments of the present invention are not limited to this. In other embodiments, an opening 114 may be formed by the single cutting process using a wider scribing knife.

Then, as shown in FIG. 1E, a second dicing process may be performed for removing a portion of wafer 10 and forming a plurality of separated chip packages. Then, the support substrate 118 may optionally be removed. Alternatively, as shown in FIG. 1F, a portion of the support substrate 118 may be removed such that the support substrate 118 underlying the plurality of chips is divided. The chip in the chip packages (diced from the wafer) may comprise the semiconductor substrate 100, the device region 102, the dielectric layer 106 and the conducting pad structure 104. In an embodiment, the sidewall of the support substrate 118 may not be coplanar with the sidewall of the chip.

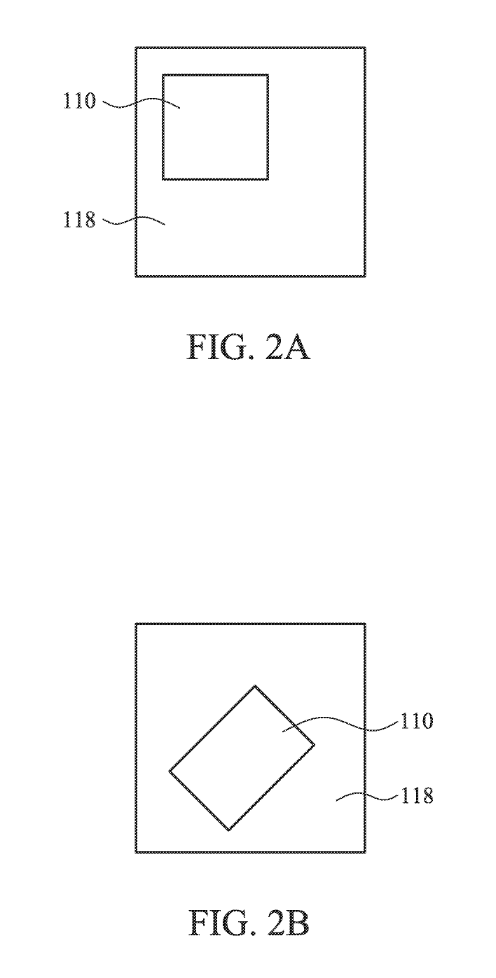

FIGS. 2A and 2B respectively show top views of the chip packages according to embodiments of the present invention, in which the same or similar reference numerals are used to refer to the same or similar devices. As shown in FIG. 2A, in an embodiment, the area of the cover substrate 110 of the chip package may be less than that of the support substrate 118. In addition, the central point of the cover substrate 110 may not overlap with the central point of the support substrate 118. That is, the cover substrate 110 may not be disposed at the central area of the support substrate 118. For instance, in the embodiment shown in FIG. 2A, the cover substrate 110 is disposed on the upper left area on the support substrate 118. In another embodiment, as shown in FIG. 2B, the sidewall of the cover substrate 110 may be not parallel to any sidewalls of the support substrate 118.

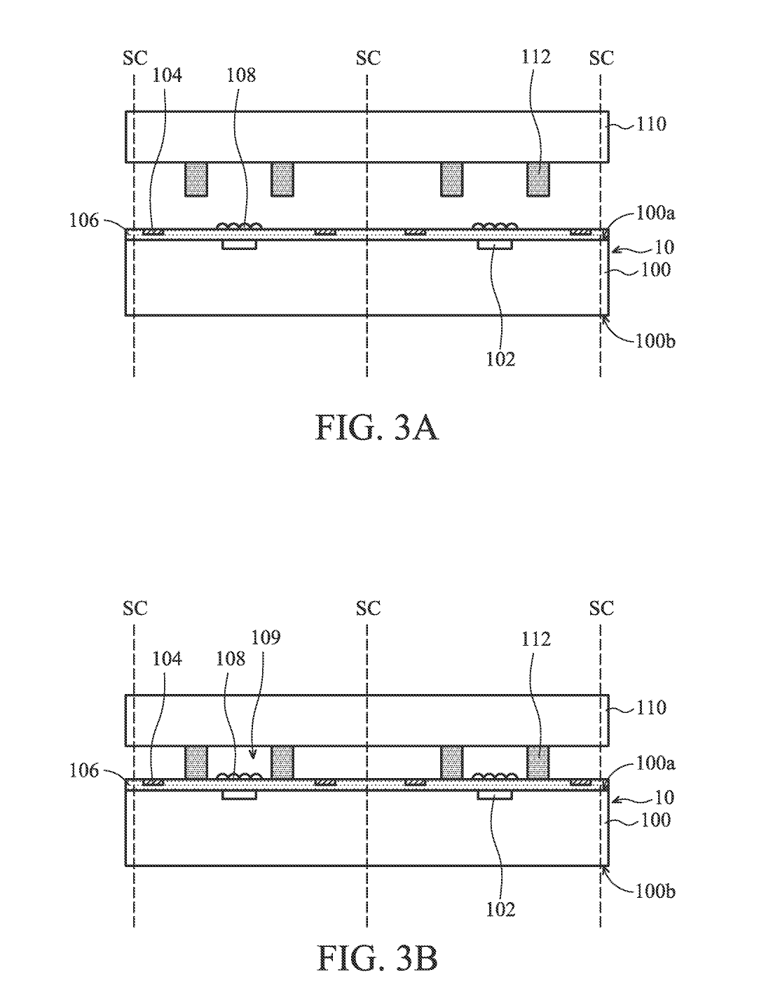

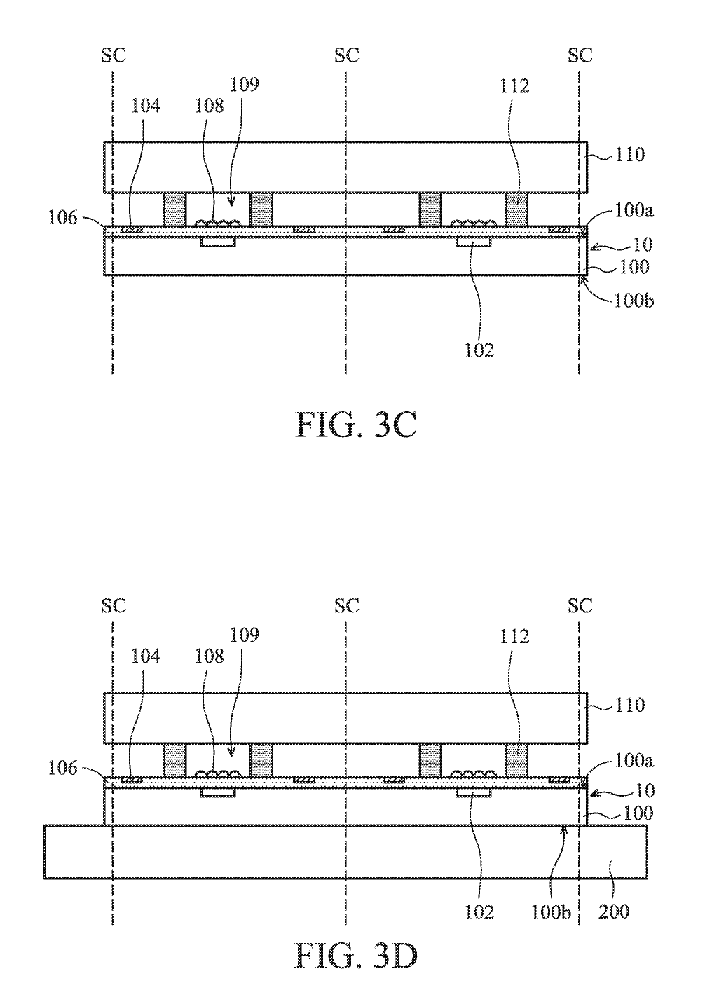

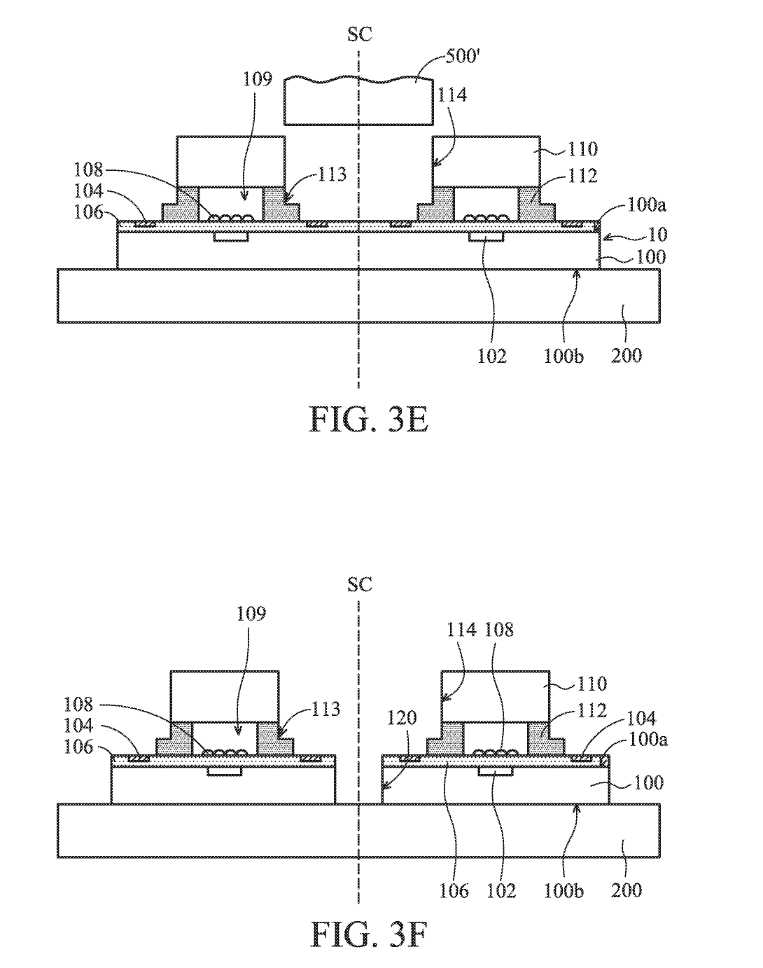

FIGS. 3A-3F show cross-sectional views of the formation of a chip package according to an embodiment of the present invention, in which the same or similar reference numerals are used to refer to the same or similar devices. As shown in FIGS. 3A-3C, a structure shown in FIG. 3C is formed by using steps similar to FIGS. 1A-1C. A wafer 10 may then be optionally disposed on a support substrate. In an embodiment, the support substrate may be a dicing tape 200, as shown in FIG. 3D.

Then, a dicing process may be performed along a plurality of predetermined scribe lines SC of the wafer 10 for forming a plurality of separated chip packages. The dicing process may be single cutting or segmented cutting processes. As shown in FIG. 3E, a first dicing process may be performed first for removing a portion of the cover substrate 100 so as to expose the wafer 10. In an embodiment, the first dicing process further removes a portion of the spacer layer 112 and forms at least one recess 113 in the spacer layer 112. In an embodiment, the sidewall of the spacer layer 112 (for example, the sidewall of the recess 113) may be substantially coplanar with the sidewall of the cover substrate 110. In an embodiment, a wider scribing knife 500′ may be used for forming an opening 114 of the wafer 10 by a single cutting process.

However, it should be noted that the embodiments of the present invention are not limited to this, the first dicing process further comprises dicing a first portion and a second portion of the cover substrate 110 at different times such that a portion of the cover substrate 110 between the first and second portions of the cover substrate 110 may be separated naturally. For example, a portion of the cover substrate 110 at a left side of the scribe line SC and a portion of the cover substrate 110 at a right side of the scribe line SC are diced at different times such that the middle portion of the cover substrate 110 can be separated naturally.

Then, as shown in FIG. 3F, a second dicing process may be performed for removing a portion of the wafer 10 and forming a plurality of separated chip packages. Then, the dicing tape 200 may optionally be removed, and the chip packages are detached.

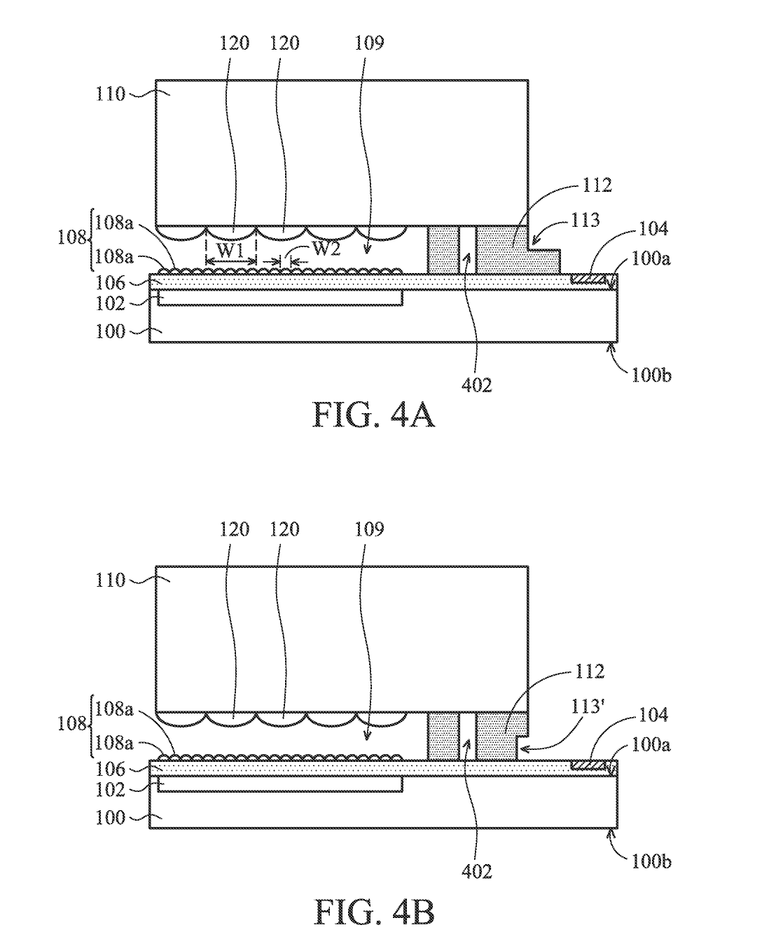

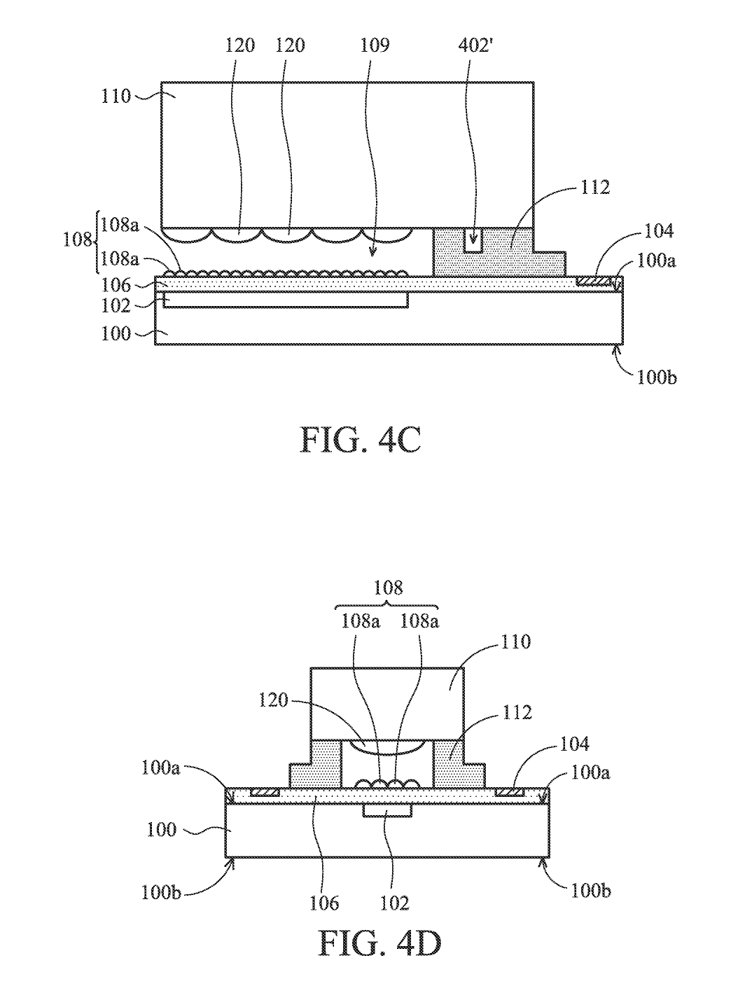

There are many variations of the embodiments of the present invention. For example, FIGS. 4A-4D show cross-sectional views of chip packages according to embodiments of present invention, in which the same or similar reference numerals are used to refer to the same or similar devices.

As shown in FIG. 4A, in an embodiment, a hole 402 may be formed in the spacer layer 112. For example, the hole 402 may penetrate through the spacer layer 112. Alternatively, as shown in FIG. 4C, a hole 402′ that does not penetrate through the spacer layer 112 may be formed in the spacer layer 112. As shown in FIG. 4B, the sidewall of the recess 113′ of the spacer layer 112 may not be coplanar with the sidewall of the cover substrate 110. As shown in FIGS. 4A-4D, one or more main lens(es) 120 may be optionally formed on the cover substrate 110, and the optical element 108 may have micro-lenses 108a, wherein the width W1 of each main lens 120 is greater than the width W2 of each micro-lens 108a (as shown in FIG. 4A). One main lens 120 may correspond to the micro-lenses 108a thereunder. The methods for forming the main lenses 120 include, for example, coating a transparent photoresist layer on the cover substrate 110, and then performing a photolithography process to the transparent photoresist layer to form the main lenses 120.

The spacer layer 112 may be a stack of a plurality of patterned material layers formed by performing multiple deposition, exposure and development processes. Alternatively, the spacer layer 112 may be a single layer of the patterned spacer material.

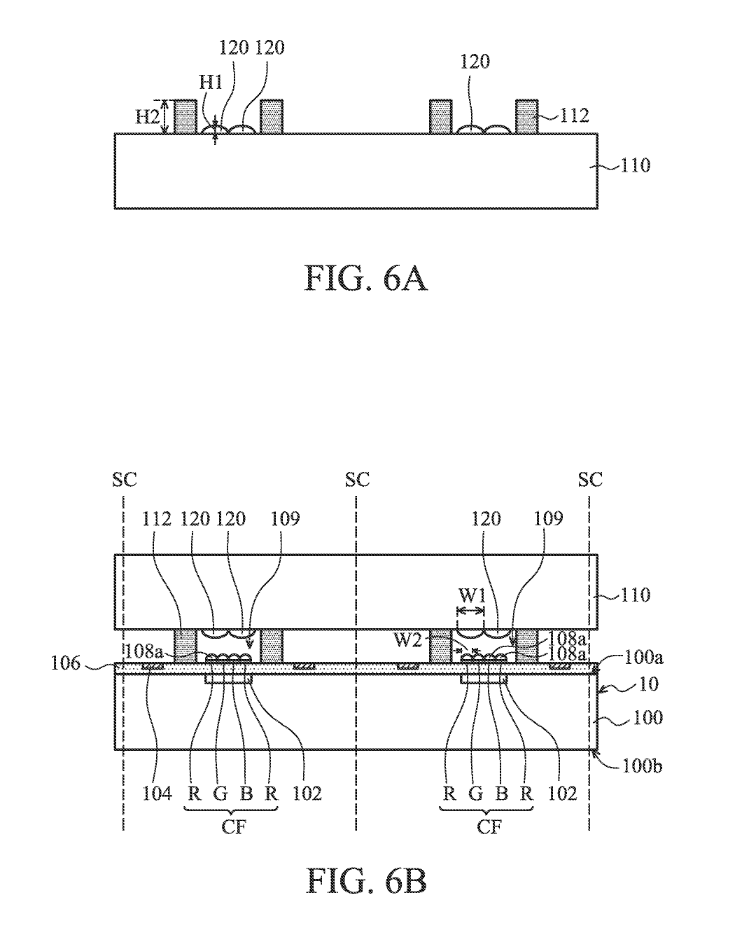

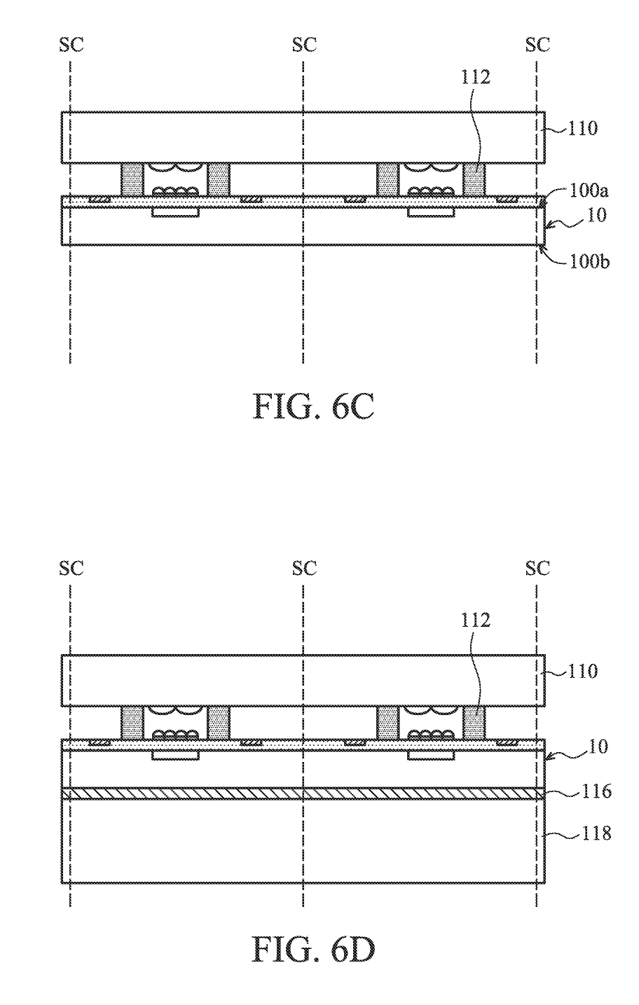

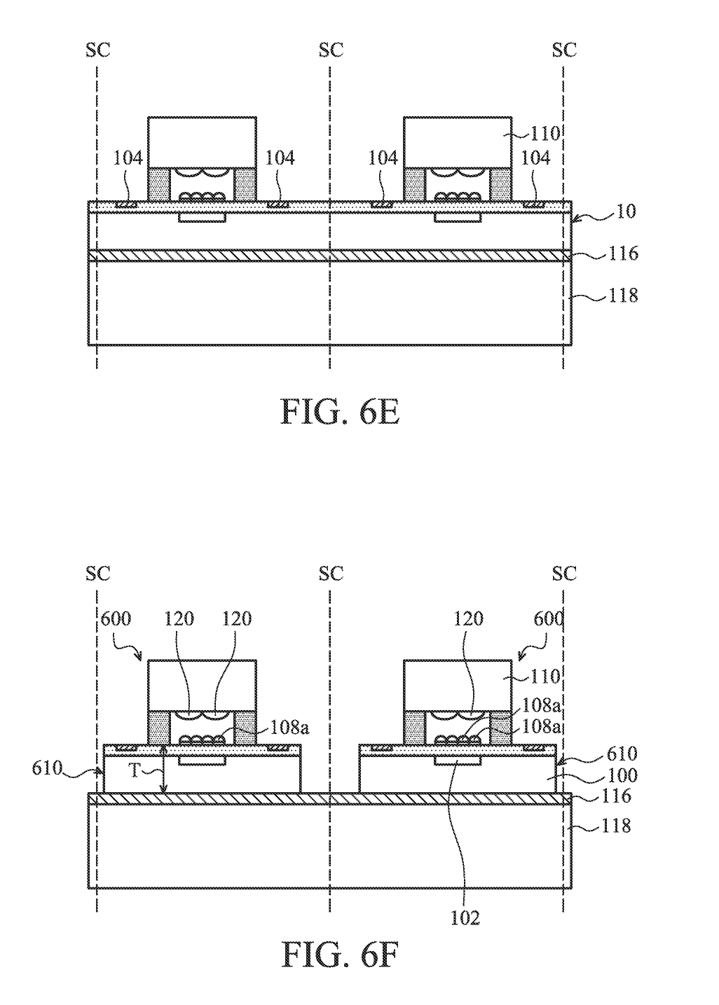

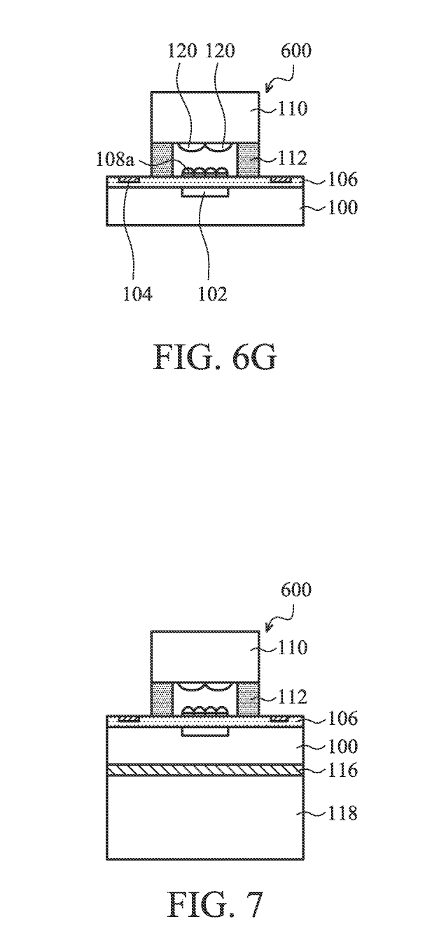

FIGS. 6A-6G show cross-sectional views of the formation of a chip package according to an embodiment of the present invention. It should be noted that the embodiment of FIGS. 6A-6G is similar to that of FIGS. 1A-1F, and thus the elements with the same reference number may have the same structure and the same material, and thus are not repeated herein.

Firstly, referring to FIG. 6A, a cover substrate 110 is provided, and main lenses 120 and a spacer layer 112 are formed on the cover substrate 110. The cover substrate 110 is, for example, a transparent substrate, such as a glass substrate. The glass substrate is, for example, an infrared glass substrate. In one embodiment, the spacer layer 112 may first be formed on the cover substrate 110, and then the main lenses 120 are formed. In this case, because the main lenses 120 are formed after the forming of the spacer layer 112, which protects the main lenses 120 from being contaminated by the process of the spacer layer 112.

In another embodiment, the main lenses 120 may first be formed on the cover substrate 110, and then the spacer layer 112 is formed. In this case, because the height H1 of the main lens 120 is much less than the height H2 of the spacer layer 112, the uniformity of the heights of the main lenses 120 formed first is due to the flat surface of the cover substrate 110 facilitating a uniform coating, and the uniformity of the heights of the spacer layer 112 formed second is also due to the height H1 of the main lens 120 being very small.

In one embodiment, the spacer layer 112 is a transparent film. In this case, the steps for forming the spacer layer 112 may be described as follows. A transparent material layer (such as a transparent photoresist material, not shown) is fully coated on the cover substrate 110. Although the transparent material layer covers alignment marks (not shown) on the cover substrate 110, the transparent material layer is light transmissive, so the alignment marks may be accurately detected to perform a photolithography process, so as to pattern the transparent material layer.

In one embodiment, the material of the spacer layer 112 is a photoresist layer with viscosity while being heated and/or compressed. Therefore, during the subsequent wafer-bonding process, the spacer layer 112 may be compressed and/or heated to have viscosity so as to directly adhere to the cover substrate 110 and the wafer.

Referring to FIG. 6B, a wafer 10 is provided. The wafer 10 includes a semiconductor substrate 100, device regions 102 and micro-lenses 108a. The semiconductor substrate 100 has a surface 100a, and the device regions 102 are formed in the semiconductor substrate 100. Various devices, such as optoelectronic devices, may be formed in the device regions 102. The optoelectronic devices may be, for example, image-sensing devices. The micro-lenses 108a are disposed on the surface 100a and on the device regions 102. The wafer 10 may have predetermined scribing lines SC.

In one embodiment, the wafer 10 may further include a dielectric layer 106 and a conducting pad structure 104. The dielectric layer 106 is disposed on the surface 100a, and the conducting pad structure 104 is disposed in the dielectric layer 106 and electrically connected to the device regions 102. Specifically, the projection of the spacer layer 112 on the surface 100a may be between the projection of the conducting pad structure 104 on the surface 100a and the projection of the device region 102 on the surface 100a. In brief, the spacer layer 112 may be located between the conducting pad structure 104 and the device region 102. In other embodiments not shown, the spacer layer 112 may be located on the conducting pad structure 104.

In one embodiment, a color filter layer CF may be formed on the device regions 102, wherein the color filter layer CF has red filter films R, green filter films G and blue filter films B, and the micro-lenses 108a are located on the red filter films R, the green filter films G and the blue filter films B, respectively.

Then, the cover substrate 110 is flipped and is disposed on the wafer 10, such that the spacer layer 112 is located between the wafer 10 and the cover substrate 110, wherein cavities 109 may be created and surrounded by the spacer layer 112, the wafer 10 and the cover substrate 110. Each cavity 109 is located on a corresponding device region 102, and each cavity 109 accommodates micro-lenses 108a and one or more main lens(es) 120.

Although, FIG. 6B depicts one cavity 109 accommodating the main lenses 120, the present invention is not limited thereto. In another embodiment, one cavity 109 may accommodate only one main lens 120, as shown in FIG. 4D. In this case, the main lens 120 corresponds to all of the micro-lenses 108a in the cavity 109.

It should be noted that the width W1 of each main lens 120 is greater than the width W2 of each micro-lens 108a (such as about 90 nm). In one embodiment, the projection of the main lens 120 on the surface 100a overlaps the projections of at least two micro-lenses 108a on the surface 100a. That is, one main lens 120 may be located right above the micro-lenses 108a at the same time. For example, the projection of a main lens 120 on the surface 100a overlaps three micro-lenses 108a respectively located on the red filter film R, the green filter film G and the blue filter film B (not shown).

It should be noted that, although the present embodiment illustrates the forming of the spacer layer 112 on the cover substrate 110, the present invention is not limited thereto. In other embodiments, the spacer layer 112 may be formed on the wafer 10 first, ant then the cover substrate 110 with the main lenses 120 is assembled with the wafer 10.

Then, referring to FIG. 6C, a thinning process is performed on the wafer 10 from the surface 100b. Then, referring to FIG. 6D, in one embodiment, the wafer 10 is disposed on a support substrate 118 to support the thinned wafer 10 by using the support substrate 118 so as to improve the yield of the subsequent dicing process. For example, the wafer 10 is bonded to the support substrate 118 through an adhesion layer 116. The support substrate 118 is, for example, a semiconductor substrate, a ceramic substrate, a polymer substrate or combinations thereof. In one embodiment, the support substrate 118 is a glass substrate.

Then, a dicing process may be performed along the predetermined scribing lines SC of the wafer 10 to form chip packages separated from each other. The dicing process may be a single cutting or segmented cutting processes. As shown in FIG. 6E, a first dicing step may be performed first to remove a portion of the cover substrate 110 to expose the wafer 10. Specifically, the first dicing step may expose the conducting pad structures 104 which are originally under the cover substrate 110. Then, as shown in FIG. 6F, a second dicing step may be performed along the predetermined scribing lines SC to remove a portion of the wafer 10 and to form chip packages 600 separated from each other.

A chip (cut from the wafer) in the chip package 600 may include a semiconductor substrate 100, a device region 102 and micro-lenses 108a. In one embodiment, the chip 610 is a chip processed by a thinning process, and the thickness T of the chip 610 ranges from about 20 μm to about 50 μm.

It should be noted that the present embodiment forms the main lens 120 and the micro-lenses 108a in a single chip package 600, such that the chip package 600 with a small size may have the functions of a conventional optical lens with a large size, and thus the chip package 600 may replace the conventional optical lens to effectively reduce the total volume of optical apparatuses (such as cameras).

Then, as shown in FIG. 6G, the support substrate 118 and the adhesion layer 116 may be optionally removed to form the chip packages 600 of the present embodiment. Alternatively, as shown in FIG. 7, FIG. 7 shows a cross-sectional view of a chip package according to another embodiment of the present invention. In the second dicing step, a portion of the support substrate 118 may be also cut to separate the support substrate 118 under the chip packages 600 to support the corresponding chip packages 600.

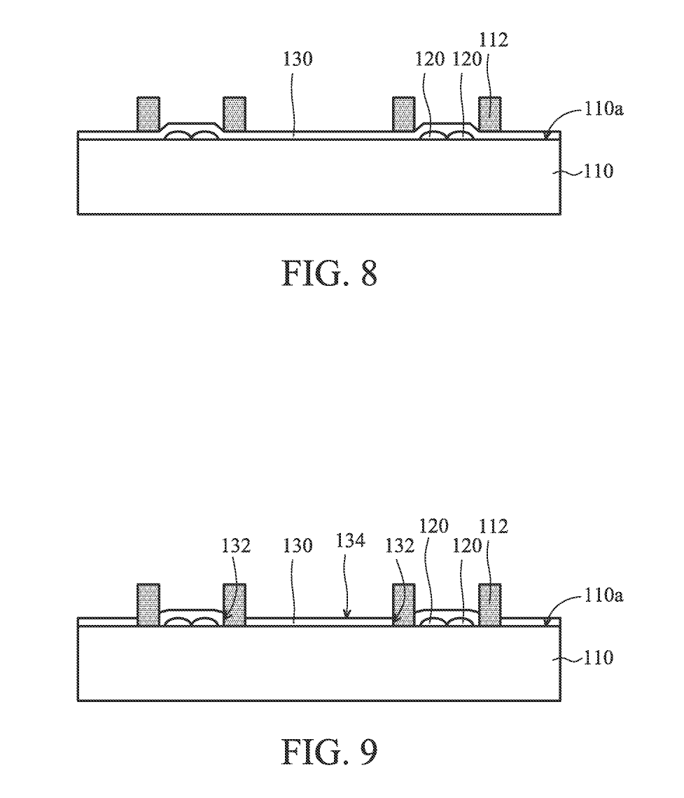

FIG. 8 shows a cross-sectional view of a portion of the formation of a chip package according to an embodiment of the present invention. The present embodiment is a variation of the process step of FIG. 6A. In another embodiment, as shown in FIG. 8, before forming the spacer layer 112, a transparent planar layer 130 covering the main lens 120 is formed on the surface 110a of the cover substrate 110, and the spacer layer 112 subsequently formed is formed on the transparent planar layer 130.

As a result, the subsequent processes (such as the process of forming the spacer layer 112) may be performed on a more planar surface, and the main lenses 120 are protected from the contamination of the subsequent processes (such as the process of forming the spacer layer 112).

In one embodiment, the process of forming the transparent planar layer 130 includes, for example, performing a chemical vapor deposition process on the surface 110a of the cover substrate 110 to form an oxide layer covering the main lenses 120. In another embodiment, the transparent planar layer 130 includes, for example, polymer materials or other suitable transparent insulating materials.

FIG. 9 shows cross-sectional views of a portion of the formation of a chip package according to an embodiment of the present invention. The present embodiment is a variation of the process of FIG. 6A. As shown in FIG. 9, in another embodiment, before forming the spacer layer 112, a transparent planar layer 130 covering the main lens 120 is formed on the surface 110a, and then the transparent planar layer 130 is patterned to form openings 132 exposing the surface 110a. Then, the spacer layer 112 penetrating the openings 132 is formed on the cover substrate 110 and protrudes from the surface 134 of the transparent planar layer 130. In this case, the transparent planar layer 130 may protect the main lenses 120 from the contamination of the subsequent processes (such as the process of forming the spacer layer 112).

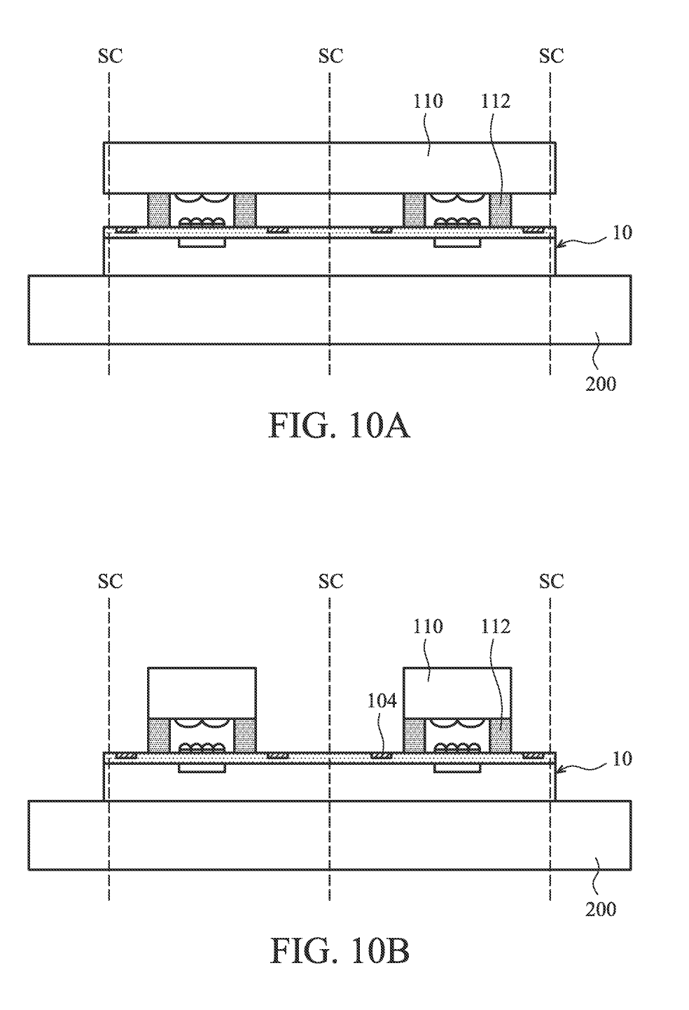

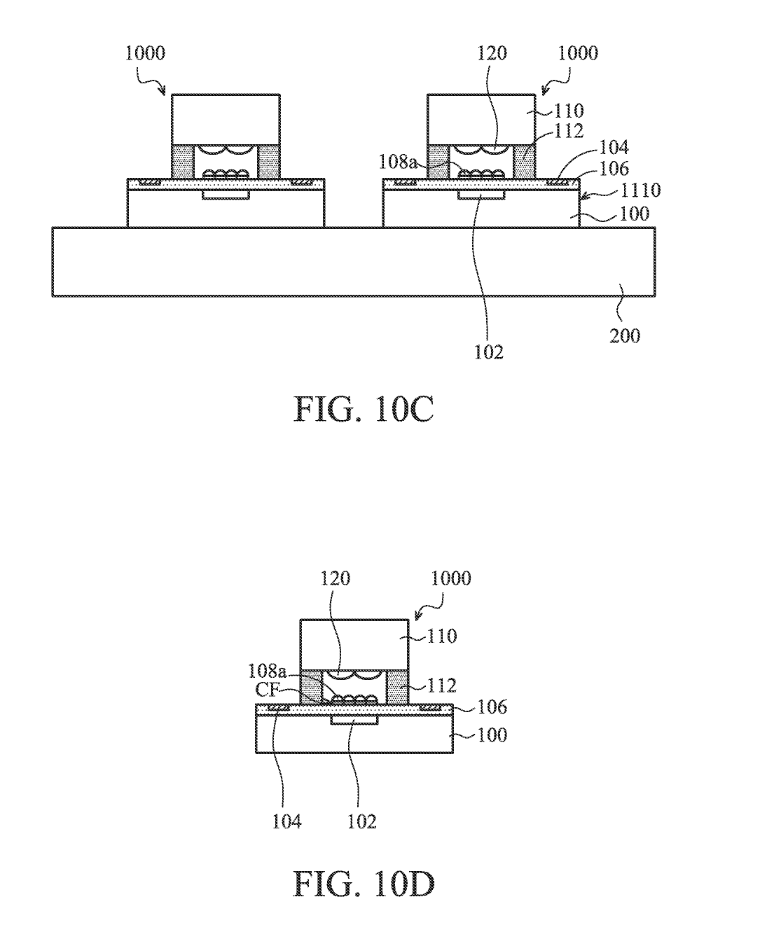

FIGS. 10A-10D show cross-sectional views of the formation of a chip package according to an embodiment of the present invention. It should be noted that the present embodiment is similar to that of FIGS. 6A-6G, except that the support substrate of the present embodiment is a dicing tape, and thus the same details of the process are not repeated herein.

Firstly, the process of FIGS. 6A-6C is performed. Then, as shown in FIG. 10A, a wafer 10 is disposed on a support substrate, and the support substrate may be a dicing tape 200.

Then, a dicing process is performed along predetermined scribing lines SC of the wafer 10 to form chip packages separated form each other. The dicing process may be single cutting or segmented cutting processes.

As shown in FIG. 10B, a first dicing step may be performed first to remove a portion of the cover substrate 110 to expose the wafer 10. Then, as shown in FIG. 10C, a second dicing step may be performed to remove a portion of the wafer 10 and to form chip packages 1000 separated from each other. A chip (cut from the wafer) 1110 in the chip package 1000 may include a semiconductor substrate 100, a device region 102 and micro-lenses 108a.

Then, as shown in FIG. 10D, the dicing tape 200 may optionally be removed, and the chip packages 1000 may be removed from the dicing tape 200.

The chip package technology provided by the embodiments of the present invention may reduce the sizes of the chip packages, fabricate the chip packages in mass production, ensure the quality of the chip packages, and/or reduce the time and cost of fabrication.

The present embodiments of the present invention forms the main lens and the micro-lenses in a single chip package, such that the chip package with a small size may have functions of a conventional optical lens with a large size, and thus the chip package may replace the conventional optical lens to effectively reduce the volume of optical apparatuses.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a chip, comprising:
a semiconductor substrate having a first surface and a second surface;
a device region formed in the semiconductor substrate;
a dielectric layer disposed on the first surface; and
a conducting pad structure disposed in the dielectric layer and electrically connected to the device region;
a cover substrate disposed on the chip; and
a spacer layer disposed between the chip and the cover substrate, wherein a cavity is created and surrounded by the spacer layer, the chip and the cover substrate on the device region, and wherein the spacer layer directly contacts the chip, and no adhesive glue is disposed between the chip and the spacer layer.

2. The chip package as claimed in claim 1, wherein the cover substrate is a transparent substrate.

3. The chip package as claimed in claim 1, wherein a projection of the spacer layer on the first surface is located between a projection of the conducting pad structure on the first surface and a projection of the device region on the first surface.

4. The chip package as claimed in claim 1, wherein a projection of the spacer layer on the first surface does not overlap a projection of the conducting pad structure on the first surface.

5. The chip package as claimed in claim 1, wherein the spacer layer directly contacts the cover substrate.

6. The chip package as claimed in claim 1, wherein the spacer layer has a recess, and a sidewall of the spacer layer is substantially coplanar with a sidewall of the cover substrate.

7. The chip package as claimed in claim 6, wherein the sidewall of the spacer layer is a sidewall of the recess.

8. The chip package as claimed in claim 6, further comprising a hole in the spacer layer.

9. The chip package as claimed in claim 8, wherein the hole penetrates through the spacer layer.

10. The chip package as claimed in claim 1, further comprising a support substrate disposed on the second surface of the semiconductor substrate.

11. The chip package as claimed in claim 10, wherein a sidewall of the support substrate is not coplanar with a sidewall of the chip.

12. The chip package as claimed in claim 11, wherein the support substrate is a glass substrate.

13. The chip package as claimed in claim 12, wherein the size of the area of the cover substrate is less than the area of the support substrate.

14. The chip package as claimed in claim 13, wherein a sidewall of the cover substrate is not parallel to any sidewalls of the support substrate.

15. The chip package as claimed in claim 13, wherein a central point of the cover substrate does not overlap with a central point of the support substrate.

16. The chip package as claimed in claim 1, further comprising an optical element disposed on the device region and in the cavity.

17. The chip package as claimed in claim 1, wherein the spacer layer directly contacts the semiconductor substrate, the dielectric layer, an optical layer on the semiconductor substrate or a flat layer on the semiconductor substrate of the chip.

18. The chip package as claimed in claim 1, wherein the spacer layer comprises a stack of a plurality of material layers.

19. The chip package as claimed in claim 1, wherein the chip further comprises a plurality of micro-lenses disposed on the first surface and on the device region, and the chip package further comprises at least one main lens disposed on the cover substrate and in the cavity, wherein a width of the main lens is greater than a width of each of the micro-lenses.

20. The chip package as claimed in claim 19, wherein the at least one main lens comprises a plurality of main lenses.

21. The chip package as claimed in claim 19, wherein a projection of the main lens on the first surface overlaps projections of at least two of the micro-lenses on the first surface.

22. The chip package as claimed in claim 19, further comprising:
a color filter layer disposed on the device region, wherein the color filter layer has at least one red filter film, at least one green filter film and at least one blue filter film, and the micro-lenses are respectively located on the red filter film, the green filter film and the blue filter film.

23. A method for forming a chip package, comprising:
providing a wafer, comprising:
a semiconductor substrate having a first surface and a second surface;
a plurality of device regions formed in the semiconductor substrate;
a dielectric layer disposed on the first surface; and
a plurality of conducting pad structures disposed in the dielectric layer, wherein each of the conducting pad structures is electrically connected to one of the device regions, respectively;
providing a cover substrate;
forming a spacer layer on the wafer or the cover substrate;
mounting the cover substrate onto the wafer such that the spacer layer is located between the wafer and the cover substrate, wherein a plurality of cavities is created and surrounded by the spacer layer, the wafer and the cover substrate, and each of the cavities is located over one of the device regions, and wherein the spacer layer directly contacts the wafer, and there is no adhesive glue disposed between the wafer and the spacer layer; and
performing a dicing process along a plurality of predetermined scribe lines of the wafer for forming a plurality of separated chip packages.

24. A chip package, comprising:
a chip, comprising:
a semiconductor substrate having a first surface;
a device region formed in the semiconductor substrate; and
a plurality of micro-lenses disposed on the first surface and on the device region;
a cover substrate disposed on the chip, wherein the cover substrate is a transparent substrate;
a spacer layer disposed between the chip and the cover substrate, wherein a cavity is created and surrounded by the spacer layer, the chip and the cover substrate on the device region; and
at least one main lens disposed on the cover substrate and in the cavity, wherein a width of the main lens is greater than a width of each of the micro-lenses.

25. A method for forming a semiconductor structure, comprising:
providing a wafer, comprising:
a semiconductor substrate having a first surface;
a plurality of device regions formed in the semiconductor substrate; and
a plurality of micro-lenses disposed on the first surface and on the device regions;
providing a cover substrate;
forming a plurality of main lenses on the cover substrate, wherein a width of each of the main lenses is greater than a width of each of the micro-lenses;
forming a spacer layer on the wafer or the cover substrate; and
mounting the cover substrate onto the wafer such that the spacer layer is located between the wafer and the cover substrate, wherein a plurality of cavities are created and surrounded by the spacer layer, the wafer and the cover substrate, and each of the cavities is located over one of the device regions, and each of the cavities accommodates at least one of the main lenses corresponding to at least two of the micro-lenses.
